(19) United States
(12) Patent Application Publication
(10) Pub. No.: US 2013/0128435 A1
(43) Pub. Date: May 23, 2013

(54) COMPOSITION, COMPOSITION BEING FOR END-FACE SEALING DISPLAY DEVICES AND CONSISTING OF THE COMPOSITION, DISPLAY DEVICES, AND PROCESS FOR PRODUCING SAME

(71) Applicants: Yasushi Mizuta, Ichihara-shi (JP); Hiroaki Otsuka, Ichihara-shi (JP); Toshikazu Gomi, Ichihara-shi (JP)

(72) Inventors: Yasushi Mizuta, Ichihara-shi (JP); Hiroaki Otsuka, Ichihara-shi (JP); Toshikazu Gomi, Ichihara-shi (JP)

(21) Appl. No.: 13/812,177

(22) PCT Filed: Jul. 29, 2011
(86) PCT No.: PCT/JP2011/004333

§ 371 Date: Jan. 25, 2013

(30) Foreign Application Priority Data
Jul. 29, 2010 (JP) 2010-170640

(51) Int. Cl. C08L 63/00; B32B 37/12; H05K 7/06

(52) U.S. Cl. CPC C08L 63/00; H05K 7/06; B32B 37/1284
USPC 361/679.01; 523/461; 523/455; 523/466; 156/305; 523/223

(57) ABSTRACT

An end-face sealing agent for display devices, which consists of a resin composition containing (1) a liquid epoxy resin, (2) an epoxy resin curing agent that is liquid at 23° C. and that is selected from the group consisting of acid anhydrides and thiol compounds having two or more mercapto groups in the molecule, (3) a secondary or tertiary amine that is solid at 233° C., or microcapsules that contain a secondary or tertiary amine therein, and (4) a filler, and in which the content of the component (4) is 50 to 150 parts by weight relative to 100 parts by weight of the sum total of the components (1), (2) and (3), and the viscosity as determined using an E-type viscometer at 253° C. and 2.5 rpm is 0.5 to 50 Pas.

### TECHNICAL FIELD

The present invention relates to a composition, a display edge-face sealing agent prepared from the composition, a display apparatus and a process for manufacturing the same.

### BACKGROUND ART

Recently, liquid crystal displays, organic EL displays and electrophoretic displays have been used as displays for various electronics. Typically, these displays are constructed as a laminate having display devices such as liquid crystal elements and a pair of substrates sandwiching the devices, the laminate having a structure in which the peripheral portion thereof is sealed with a sealing member.

The liquid crystal display is manufactured for instance by (1) forming a frame to be filled with a liquid crystal by applying a liquid crystal sealing agent onto a transparent substrate, (2) adding dropwise fine liquid crystals inside the frame, (3) overlaying two substrates on top of each other under high vacuum while keeping the liquid crystal sealing agent in an uncured state, and (4) curing the liquid crystal sealing agent.

For example, a liquid crystal sealing agent containing an epoxy resin that is less soluble in a liquid crystal and an epoxy resin curing agent is proposed as the liquid crystal sealing agent (see, e.g., PTL 1).

On the other hand, a display having, for example, a micro cup structure is proposed as the electrophoretic display (see, e.g., PTL 2). Such an electrophoretic display is manufactured by (1) providing a laminate having display devices and a pair of substrates sandwiching the devices, and (2) using a sealing agent to seal the gap between the substrates, which gap is formed in the peripheral edge portion of the laminate.

### CITATION LIST

### Patent Literature

PTL 1
Japanese Patent Application Laid-Open No. 2005-018022
PTL 2
Japanese Unexamined Patent Application Publication (Translation of PCT application) No. 2004-536332

### SUMMARY OF INVENTION

### Technical Problem

As previously described, when manufacturing an electrophoretic display, a thin gap formed between the edge faces of substrates is sealed with a sealing member after a laminate having a display element sandwiched by a pair of substrates is assembled. Thus, it is desirable that the sealing agent have a viscosity low enough for it to move even into a thin gap as well as be able to maintain that low level of viscosity (i.e., has excellent viscosity stability).

On the other hand, it is desired that a cured material of a sealing agent is highly moisture resistant to protect the display element against possible damages resulting from external moisture and/or the like. Accordingly, the sealing agent preferably contains a large amount of filler. A high filler content may, however, significantly increase the viscosity of the sealing agent. Thus, it has been required in the art to develop a sealing agent having viscosity stability and a viscosity low enough for it to move even into a thin gap, and to provide a cured material which is highly moisture resistant.

The present invention was made in consideration of the above circumstances. An object of the present invention is to provide a composition having viscosity stability and a viscosity low enough for it fill a thin gap, and to provide a cured material having high moisture resistance, a display edge-face sealing agent including the composition, a display apparatus using the sealing agent, and a process for manufacturing the display apparatus.

### Solution to Problem

The present inventors conducted studies in order to reduce the viscosity of a composition to a level sufficient for it to fill a thin gap, and found that low viscosity and high moisture resistance can be achieved by using (1) liquid epoxy resin and a (2) liquid epoxy resin curing agent, and by controlling the amount of filler.

On the other hand, because a composition containing a plurality of liquid components exhibits relatively high reactivity, the viscosity stability decreases so that thin-gap filling becomes difficult. Furthermore, a composition containing a liquid epoxy resin curing agent alone as a curing agent tends to have a relatively low curing rate. The present inventors have found that not only the viscosity stability of the composition but also the curing rate can be enhanced by adding a (3) solid secondary or tertiary amine or microcapsules encapsulating a secondary or tertiary amine into the composition. The present invention was made based on such findings.

A first aspect of the claimed invention is as follows:

[1] A resin composition containing (1) an epoxy resin that is liquid at 23° C.;

(2) an epoxy resin curing agent that is liquid at 23° C., the epoxy resin curing agent being selected from the group consisting of an acid anhydride and a thiol compound having two or more mercapto groups in a molecule thereof;

(3) a secondary or tertiary amine that is solid at 23° C., or microcapsules encapsulating therein the secondary or tertiary amine; and

(4) a filler, wherein

an amount of the component (4) in the composition is 50 to 150 parts by weight based on 100 parts by weight of the total amount of the components (1), (2) and (3), and

the composition has a viscosity at 25° C. and 2.5 rpm of 0.5 to 50 Pa·s as measured by an E-type viscometer.

A second aspect of the claimed invention is as follows:

[2] A composition for a display edge-face sealing agent including the composition according to [1].

[3] The composition according to [1] or [2], wherein the composition has a moisture content of 0.5 wt % or less.

[4] The composition according to any one of [1] to [3], wherein the filler includes an inorganic filler and an organic filler.

[5] The composition according to any one of [1] to [4], wherein the filler is a spherical filler having an average particle size of 0.1 to 20 μm.

[6] The composition according to any one of [1] to [5], wherein the epoxy resin that is liquid at 23° C. is at least one resin selected from the group consisting of bisphenol A epoxy resin, bisphenol F epoxy resin, bisphenol E epoxy resin and polysulfide modified epoxy resin.

[7] The composition according to any one of [1] to [6], wherein the content ratio of the component (3) to the component (2) in terms of weight is 0.2 to 1.2.

[8] The composition according to any one of [1] to [7], wherein the secondary or tertiary amine that is solid at 23° C. is in the form of fine particles having a melting point of 60 to 180° C. selected from the group consisting of an imidazole compound, and a modified polyamine; and

the fine particles have an average particle size of 0.1 to 10 μm.

[9] The composition according to any one of [1] to [7], the microcapsules each includes:

a core formed of at least one secondary or tertiary amine selected from the group consisting of an imidazole compound and a modified polyamine; and

a capsule wall having a melting point of 60 to 180° C., the capsule wall encapsulating the secondary or tertiary amine, and wherein

the microcapsules have an average particle size of 0.1 to 10 μm.

[10] The composition according to any one of [4] to [9], wherein the organic filler is at least one fine particle having a melting point or softening point of 60 to 120° C. selected from the group consisting of a silicon fine particle, an acrylic fine particle, a styrene fine particle, and a polyolefin fine particle, or at least one wax selected from the group consisting of carnauba wax, a microcrystalline wax, a modified microcrystalline wax, Fischer-Tropseh wax, and a modified Fischer-Tropsch wax.

[11] The composition according to any one of [1] to [10], wherein a film having a thickness of 100 μm obtained by heat curing of the composition at 80° C. for 60 minutes has a glass transition temperature Tg of 30 to 110° C. as measured by DMS at a rate of temperature increase of 5° C./min.

[12] The composition according to any one of [1] to [10], wherein a film having a thickness of 100 μm obtained by heat curing of the composition at 80° C. for 60 minutes has a glass transition temperature Tg of 10 to 40° C. as measured by DMS at a rate of temperature increase of 5° C./min.

[13] The composition according to any one of [2] to [12], wherein the display apparatus displays information by an electrophoretic system.

[14] The composition according to any one of [2] to [13], wherein the display apparatus is an electronic paper display.

A third aspect of the claimed invention is as follows:

[15] A display apparatus including:

a display element;

a pair of substrates sandwiching the display element; and

a cured material from the composition according to any one of [1] to [14] sealing a gap between the pair of substrates, the gap being formed in a peripheral edge portion of the pair of substrates.

[16] The display apparatus according to [15], wherein

one of the pair of substrates is a glass substrate and the other is a resin sheet; and

the cured material has a glass transition temperature Tg of 30 to 110° C. as measured by DMS at a thickness of 100 μm and at a rate of temperature increase of 5° C./min.

[17] The display apparatus according to [15], wherein

the pair of substrates are both glass substrates or resin sheets, and

the cured material has a glass transition temperature Tg of 10 to 40° C. as measured by DMS at a rate of temperature increase of 5° C./min, where the cured material has a thickness of 100 μm.

[18] The display apparatus according to [15], wherein the gap between the pair of substrates has a size of 20 to 500

[19] A process for manufacturing a display apparatus,

providing a laminate having a display element and a pair of substrates sandwiching the display element;

applying or adding dropwise the composition according to any one of [1] to [14] to a gap between the pair of substrates, the gap being formed in a periphery edge portion of the laminate; and

curing the display edge-face sealing agent applied or added dropwise.

### Advantageous Effects of Invention

According to the present invention, it is possible to provide a composition having viscosity stability and a viscosity low enough for it to fill even a thin gap, a cured material that is highly moisture resistant, and a display edge-face sealing agent including the composition.

### BRIEF DESCRIPTION OF DRAWING

FIG. 1 is a schematic view showing an embodiment of a display apparatus of the claimed invention.

### DESCRIPTION OF EMBODIMENTS

1. Composition

The composition of the present invention contains a liquid epoxy resin (1); a liquid epoxy resin curing agent (2); a solid secondary or tertiary amine or microcapsules encapsulating therein a secondary or tertiary amine (3); and a filler (4). In addition to the abovementioned components, an optional component (5) such as a silane coupling agent may be included.

(1) Liquid Epoxy Resin

The liquid epoxy resin is an epoxy resin that is liquid at 23° C. The liquid epoxy resin is not particularly limited as long as it has two or more epoxy groups in one molecule and the epoxy resin is liquid at normal temperature (23° C.). Examples of the liquid epoxy resin include bisphenol epoxy resins such as bisphenol A epoxy resin, bisphenol F epoxy resin, bisphenol E epoxy resin, bisphenol S epoxy resin, bisphenol AD epoxy resin and hydrogenated bisphenol A epoxy resin; diphenylether epoxy resin; novolak epoxy resins such as phenol novolak epoxy resin, cresol novolak epoxy resin, biphenyl novolak epoxy resin, bisphenol novolak epoxy resin, naphthol novolak epoxy resin, trisphenol novolak epoxy resin and dicyclopentadiene novolak epoxy resin; biphenyl epoxy resins; naphthyl epoxy resins; triphenolalkane epoxy resins such as triphenolmethane epoxy resin, triphenolethane epoxy resin and triphenolpropane epoxy resin; alicyclic epoxy resins; aliphatic epoxy resins; polysulfide modified epoxy resins; resorcinol epoxy resins; and glycidylamine epoxy resins.

Examples of the glycidylamine epoxy resins include epoxy resins having an N-glycidyl group represented by the following formula in the molecule.

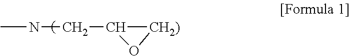

Furthermore, the glycidylamine epoxy resins preferably have two or more glycidyl groups in the molecule and one or more benzene nuclei. Such a compound, which can be obtained by reacting one or two epihalohydrins with an amino group of an aromatic amine compound, is a compound having a monoglycidylamino group or a diglycidylamino group. Specific examples of the glycidylamine epoxy resins include N,N-bis(2,3-epoxypropyl)-4-(2,3-epoxypropoxy)methylaniline and N,N,N′,N′-tetraglycidyl-4,4′-diaminodiphenylmethane.

Of the epoxy resins, bifunctional epoxy resins are preferable since they have relatively low crystallinity, satisfactory coating properties, and viscosity stability. For example, a bisphenol A epoxy resin, a bisphenol F epoxy resin, a bisphenol E epoxy resin and a polysulfide modified epoxy resin are more preferable.

The weight-average molecular weight (Mw) of the liquid epoxy resin is preferably 200 to 700, and more preferably 300 to 500. The weight-average molecular weight of the epoxy resin can be measured, for example, by gel permeation chromatography (GPC) using polystyrene as a standard.

The liquid epoxy resins may be used alone or in combinations of two or more different epoxy resins having different molecular weights.

The amount of the liquid epoxy resin is preferably 5 to 50 wt % based on the total amount of the composition, and more preferably 10 to 30 wt %.

(2) Liquid Epoxy Resin Curing Agent

The liquid epoxy resin curing agent is liquid at room temperature (23° C.), and preferably a thermosetting agent which does not rapidly cure an epoxy resin under normal storage conditions (at room temperature under visible light) but cures an epoxy resin upon application of heat. These thermosetting agents are incorporated within the cured resin as a crosslinking group.

A thermosetting agent, which cures an epoxy resin at a relatively low temperature of about 80° C., is preferred. More specifically, for example, an acid anhydride and a thiol compound having two or more mercapto groups in the molecule thereof are preferred.

Examples of the acid anhydride include aromatic acid anhydrides such as phthalic anhydride; alicyclic acid anhydrides such as hexahydrophthalic anhydride, 4-methylhexahydrophthalic anhydride, tetrahydrophthalic anhydride, methylbicyclo[2.2.1]heptane-2,3-dicarboxylic acid anhydride and bicyclo[2.2.1]heptane-2,3-dicarboxylic acid anhydride; and aliphatic acid anhydrides such as succinic anhydride. These can be used alone or as a mixture of two or more. Of them, an alicyclic acid anhydride is preferred since it is a low viscous liquid at room temperature.

Examples of the thiol compound having two or more mercapto groups in the molecule include ester compounds obtained by reacting a mercapto group-containing carboxylic acid and a polyvalent alcohol. Examples of the mercapto group-containing carboxylic acid include mercapto group-containing aliphatic carboxylic acids such as 2-mercaptopropionic acid, 2-mercaptoisobutyric acid and 3-mercaptoisobutyric acid.

Examples of the polyvalent alcohol include C₂₋₁₀ alkylene glycols such as ethylene glycol, trimethylene glycol, 1,2-propylene glycol, 1,2-butane diol, 2,3-butane diol, tetramethylene glycol and tetraethylene glycol, diethylene glycol, glycerin, dipropylene glycol, trimethylolpropane, ditrimethylolpropane, pentaerythritol, dipentaerythritol and 1,3,5-tris(2-hydroxyethyl)isocyanuric acid; and preferably polyvalent (trivalent or more) aliphatic alcohols such as trimethylolpropane, pentaerythritol, ditrimethylolpropane, dipentaerythritol and 1,3,5-tris(2-hydroxyethyl)isocyanuric acid are used.

The thiol compound having two or more mercapto groups in the molecule can be easily obtained as commercially available products. Examples of the commercially available thiol compound include 1,4-bis(3-mercaptobutyryloxy)butane (Karenz MT BD1, manufactured by Showa Denko K.K.), pentaerythritol tetrakis(3-mercaptobutyrate) (Karenz MT PE1, manufactured by Showa Denko K.K.), pentaerythritol tetrakis(3-mercaptopropionate (PEMP, manufactured by SC Organic Chemical Co., Ltd.), trimethylolpropane tris(3-mercaptopropionate) (TMMP, manufactured by SC Organic Chemical Co., Ltd.), dipentaerythritolhexakis(3-mercaptopropionate) (DPMP manufactured by SC Organic Chemical Co., Ltd.), bisphenol A thiol (QX-11 manufactured by Mitsubishi Chemical Corporation), tris-[(3-mercaptopropionyloxy)-ethyl]-isocyanurate (TEMPIC, manufactured by SC Organic Chemical Co., Ltd.), tetraethylene glycol bis(3-mercaptopropionate) (EGMP-4 manufactured by SC Organic Chemical Co., Ltd.), 1,2-bis(2-mercaptoethylthio)-3-mercaptopropane (manufactured by Mitsui Chemicals, Inc.), a thiol group-containing polyether polymer (Cup cure 3-800 manufactured by Japan Epoxy Resins Co., Ltd.) and 1,3,5-tris(3-mercaptobutyloxyethyl)-1,3,5-triazine-2,4,6(1H,3H, 5H)-trione (Karenz MT NR1 manufactured by Showa Denko K.K.).

To attain an appropriate viscosity of the composition, a liquid epoxy resin curing agent preferably has a number-average molecular weight of 200 to 800. When a composition containing a liquid epoxy resin curing agent having a number-average molecular weight exceeding 800 is used as a sealing agent, the viscosity increases, and the coating properties and gap filling properties thereof easily deteriorate. In contrast, if a composition containing a liquid epoxy resin curing agent having a number-average molecular weight of less than 200 is used as a sealing agent, the viscosity is so low that the form obtained by sealing sometimes cannot be stably maintained. The number-average molecular weight of the liquid epoxy resin curing agent can be determined for instance by GPC analysis.

The amount of the liquid epoxy resin curing agent is preferably 5 to 40 wt % based on the total amount of the composition, and more preferably, 10 to 30 wt %. When the amount of the liquid epoxy resin curing agent falls within the above preferred range, it is possible not only to reduce the viscosity of the composition but also to provide the cured material having an appropriate flexibility.

The total amount of the liquid epoxy resin and the (2) liquid epoxy resin curing agent is preferably 10 to 90 wt % based on the total amount of the composition, and more preferably 20 to 60 wt %. When the total amount of the component (1) and the component (2) is extremely low, an increase in the viscosity of a composition when using a large amount of filler tends to be large. In contrast, when the total amount of the component (1) and the component (2) is extremely large, the reaction between the liquid epoxy resin and the liquid epoxy resin curing agent included in the composition is likely to occur even under room temperature.

Since the composition containing such a liquid epoxy resin curing agent has low viscosity, it not only exhibits excellent coating properties but also easy to fill a thin gap, thus offering excellent sealing properties.

(3) A secondary or tertiary amine that is solid at 23° C. or a microcapsule encapsulating a secondary or tertiary amine

The secondary or tertiary amine that is solid at 23° C. or the microcapsule encapsulating a secondary or tertiary amine serves as a curing agent or a curing accelerator for a liquid epoxy resin.

Examples of the secondary or tertiary amine that is solid at 23° C. include modified polyamines, imidazole compounds, polyamide amine compounds, polyaminourea compounds, organic-acid hydrazide compounds, and organic-acid dihydrazide compounds.

The modified polyamine is a compound having a polymer structure obtained by reacting a polyamine and an epoxy resin. Examples of the polyamine of the modified polyamine include, but are not particularly limited to, primary, secondary and tertiary amines. Preferably, imidazole compounds are used.

Examples of the modified polyamine include FUJICURE FXR-1081 manufactured by Fuji Kasei Kogyo Co., Ltd., Adeka hardener EH4339S (softening point: 120 to 130° C.) manufactured by ADEKA corporation, Adeka hardener EH4342 manufactured by ADEKA corporation and Adeka hardener EH4357S (softening point 73 to 83° C.) manufactured by ADEKA corporation.

Examples of the imidazole compounds include 2-methylimidazole, 2-ethyl-4-methylimidazole, 2-isopropylimidazole, 2-undecylimidazole, 2-heptadecylimidazole, 2-phenylimidazole, 2-phenyl-4-methylimidazole, and 2-aminopropylimidazole.

A polyamide amine compound is obtained, for example, by subjecting a dicarboxylic acid and a polyamine to a dehydrative-condensation reaction. Specific examples of the polyamide amine compound include imidazolines obtained by subjecting dicarboxylic acids and ethylene diamines to a dehydrative-condensation reaction followed by cyclization.

A polyaminourea compound refers to a compound obtained by heat curing of an amine and urea. Examples of the polyaminourea compound include FUJICURE FXR-1081 (melting point: 121° C.) and FUJICURE FXR-1020 (melting point: 124° C.).

Examples of the organic-acid hydrazide compound include p-hydroxybenzoic acid hydrazide (PHBH, manufactured by Japan Finechem Company, Inc., melting point: 264° C.). Examples of the organic-acid dihydrazide compound include adipic dihydrazide (melting point: 181° C.), 1,3-bis(hydrazinocarboethyl)-5-isopropyl hydantoin (melting point: 120° C.), 7,11-octadecadiene-1,18-dicarbohydrazide (melting point: 160° C.), dodecanedioyl dihydrazide (melting point: 190° C.) and sebacic dihydrazide (melting point: 189° C.).

The melting point of the secondary or tertiary amine that is solid at 23° C. preferably falls in the vicinity of the heat curing temperature for heat curing of a composition, and more preferably 60 to 180° C. When the melting point of the secondary or tertiary amine that is solid at 23° C. is extremely low, the curing reaction of a liquid epoxy resin may occur at room temperature, thereby reducing storage stability of the composition. When the melting point of the secondary or tertiary amine that is solid at 23° C. is excessively high, a function as a curing agent or a curing accelerator is rarely exerted at the aforementioned heat curing temperature.

The average particle size of the secondary or tertiary amine that is solid at 23° C. is preferably 0.1 to 10 μm for example, and more preferably, 0.1 to 0.5 μm so as to fill a thin gap between substrates, as will be described later.

The amount of the secondary or tertiary amine that is solid at 23° C. is preferably 2 to 20 wt % based on the total amount of the composition, and more preferably 5 to 15 wt %. When the amount of the secondary or tertiary amine that is solid at 23° C. is excessively low, the effect of enhancing a curing rate of epoxy resin cannot be sufficiently obtained. In contrast, when the amount of the secondary or tertiary amine that is solid at 23° C. is excessively large, the viscosity of the composition is likely to increase.

The content ratio of the secondary or tertiary amine (3) that is solid at 23° C. to the liquid epoxy resin curing agent (2) (component (3)/component (2)) is preferably 0.2 to 1.2 by weight. When the content ratio is excessively low, the liquid epoxy resin curing agent included in the composition becomes relatively large in content, and the above amine reacts with a liquid epoxy resin even at room temperature to thereby reduce viscosity stability. In contrast, when the content ratio is excessively high, the viscosity of the composition is likely to increase.

The microcapsule encapsulating a secondary or tertiary amine include a core formed of the secondary or tertiary amine and a capsule wall encapsulating the core.

The secondary or tertiary amine serving as a core is not particularly limited and may be liquid or solid at 23° C. Examples of the secondary or tertiary amine serving as a core include the same modified polyamines and imidazole compounds as described above. The material for the capsule wall is not particularly limited, but preferably a polymer compound when considering a balance between stability of a composition during storage and activity exerted by heating. Examples of the polymer compound include polymer compounds obtained from compounds such as polyurethane compounds, polyurethane urea compounds, polyurea compounds, polyvinyl compounds, melamine compounds, epoxy resins and phenol resins. The melting point of the capsule wall is preferably 60 to 180° C. in order to allow the microcapsule to serve as a curing agent or a curing accelerator at the heat curing temperature of the composition. Examples of commercially available products of such a micro capsule include an imidazole modified microcapsule product (Novacure HX-3722 manufactured by Asahi Kasei Corporation).

The average primary particle size of microcapsules is preferably 0.1 to 10 μm, and more preferably 0.5 to 5 μm, as described above. The amount of microcapsules may be controlled such that the amount of a secondary or tertiary amine in the composition falls within the aforementioned range.

Such a composition containing a secondary or tertiary amine that is solid at 23° C. or microcapsules encapsulating a secondary or tertiary amine is less reactive with a liquid epoxy resin at room temperature, and thus storage stability thereof at room temperature is high. Furthermore, the composition containing a secondary or tertiary amine also exhibits a high curing rate.

(4) Filler

The filler can control moisture resistance and linear expansion properties of a cured material prepared from a composition. The filler may be an inorganic filler, an organic filler or any combination thereof, and is preferably a combination of an inorganic filler and an organic filler.

Examples of the inorganic filler include, but are not particularly limited to, inorganic fillers such as calcium carbonate, magnesium carbonate, barium sulfate, magnesium sulfate, aluminum silicate, zirconium silicate, iron oxide, titanium oxide, aluminum oxide (alumina), zinc oxide, silicon dioxide, potassium titanate, kaolin, talc, glass beads, sericite activated clay, bentonite, aluminum nitride, and silicon nitride. Preferably, silicon dioxide and talc are used.

The organic filler is not particularly limited. From the perspective of preventing dripping caused by melting when approaching a heat curing temperature, an organic filler having a melting point or a softening point of 60 to 120° C. is preferred. Examples of such an organic filler include fine particles selected from the group consisting of silicon fine particles, acrylic fine particles, styrene fine particles formed of a styrene-divinylbenzene copolymer, and polyolefin fine particles; and a wax selected from the group consisting of carnauba wax, a microcrystalline wax, a modified microcrystalline wax, Fischer-Tropsch wax, and a modified Fischer-Tropsch wax.

The form of the filler is not particularly limited. Either a finite form such as a spherical form, a plate form or a needle form, or a non-finite form may be used. However, from the perspective of enhancing the performance of thin gap-filling, a spherical form is preferred. The average primary particle size of the filler is preferably 0.1 to 20 μm, more preferably, 0.1 to 10 μm, and even more preferably 0.5 to 5 μm. The average primary particle size of the filler can be measured by the laser diffraction method described in HS Z8825-1.

The filler is preferably polydisperse rather than monodisperse from the view point of enhancing the performance of thin gap-filling. This is because a composition containing a highly monodispersed filler may exhibit increased viscosity and therefore reduced performance of thin gap-filling.

To limit a viscosity increase in the composition caused by aggregation of filler particles, the surface of the filler may be treated. To be more specific, since filler particles are easily aggregated by the interaction between the particles, a treatment for inactivating (non-polarizing) the surface of the filler particles is preferably applied to prevent interaction between the filler particles.

As the treatment for inactivating (non-polarizing) the surface of filler particles, any method may be employed as long as a hydrophobic group can be introduced onto the filler surface. Examples thereof include methods of treating the surface with an agent such as cyclic siloxane, a silane coupling agent, a titanate coupling agent, or hexaalkyl disilazane.

The amount of the filler is preferably 50 to 150 parts by weight, and more preferably 75 to 125 parts by weight based on 100 parts by weight of the total amount of the liquid epoxy resin (1), liquid epoxy resin curing agent (2) and secondary or tertiary amine (3). When the composition contains both an inorganic filler and an organic filler, the amount of the filler refers to the total amount of the inorganic filler and the organic filler. As described above, the composition containing a controlled amount of filler thus exhibits a proper viscosity and thus coating properties to a substrate are good and satisfactory. Furthermore, a cured material from such a composition rarely absorbs moisture and thus exhibits high adhesion reliability under humid conditions.

(5) Other Additives

The composition of the claimed invention may further contain another curing resin as long as it does not impair the effect of the claimed invention. From the perspective of enhancing the heat resistance of the composition, other examples of the curing resin include solid epoxy resins. Examples of the solid epoxy resin include solid bisphenol A epoxy resins.

Furthermore, the composition of the claimed invention may further contain one or more additives including coupling agents such as silane coupling agents, rubber agents, ion trapping agents, ion exchanging agents, leveling agents, pigments, dyes, plasticizers, and antifoaming agents, as long as these additives do not impair the effect of the claimed invention. These additives may be used alone or in combination. Examples of the above-described silane coupling agents include 3-glycidoxypropyl-trimethoxysilane.

The composition of the claimed invention further preferably contains a rubber agent in order to enhance impact resistance of the edge-face of a display apparatus and enhance adhesion to a substrate, as will be described later. Examples of the rubber agent include silicone rubber agents, acrylic rubber agents, olefin rubber agents, polyester rubber agents, and urethane rubber agents.

The composition of the claimed invention preferably has a moisture content of 0.5 wt % or less, and more preferably 0.2 wt % or less. The composition of the claimed invention is preferably used as a display edge-face sealing agent, as described later. When the sealing agent has a high moisture content, moisture easily migrates from the sealing agent into the device sealed with the sealing agent, which may affect the display apparatus. Particularly, the device which displays information in an electrophoretic system may be influenced by polar molecules such as water. In the claimed invention, the moisture content in the composition is preferably 0.5 wt % or less.

The moisture content in the composition is measured by Karl Fischer's method. To set the moisture content in the composition within the above range, raw materials with low moisture content are selected, and a composition is prepared under low moisture-content conditions. Moreover, dehydrating each raw material before preparation of the composition is preferable.

In the composition of the claimed invention, the viscosity, as measured by an E-type viscometer at 25° C. and 2.5 rpm, is preferably 0.5 to 50 Pa·s, and more preferably 1 to 20 Pa·s. When the viscosity of the composition is less than 0.5 Pa·s and is used as a sealing agent, a pattern formed by the sealing agent is rarely maintained and dripping easily occurs. In contrast, when the viscosity of a composition exceeds 50 Pa·s, the composition cannot fill a thin gap, and sealing properties tend to deteriorate. As described above, the viscosity of the composition can be controlled by the amounts of the liquid epoxy resin (1) and liquid epoxy resin curing agent (2), the form and the average primary particle size of the filler (4), and/or the like.

From the perspective of easily filling a fine gap with the composition of the claimed invention, the thixotropy index (TI value), which indicates a ratio of the viscosity measured at a relatively low shearing speed to the viscosity measured at a relatively high shearing speed (i.e., low shearing viscosity/high shearing viscosity), is preferably close to 1. The thixotropy index can be controlled for instance by the average primary particle size of the filler (4) included in the composition.

The cured material prepared from the composition of the claimed invention preferably has at least a certain level of heat resistance to maintain adhesion strength to a substrate at a high temperature when the composition is used as a sealing agent for display apparatus. A preferable heat resistance is determined in accordance with the type of substrate of a display apparatus. For example, in a display apparatus in which display devices are sandwiched between a glass substrate and a resin sheet having a linear expansion coefficient equaled or exceeding the linear expansion coefficient of the composition, when the composition of the claimed invention is used as a sealing agent for sealing the gap between the pair of substrates, the glass transition temperature (Tg) of a cured material, which is obtained by heat curing at 80° C. for 60 minutes of the claimed invention, is preferably 30 to 110° C. When the glass transition temperature of the cured material prepared from the composition falls within the above-described preferred range, the possibility of interfacial peeling and/or the like occurring between each of the substrates and the sealing agent is low, and a highly reliable display apparatus can be obtained.

In a display apparatus in which display devices are sandwiched between two resin sheets or glass substrates, when the composition of the claimed invention is used as a sealing agent for sealing the gap between the pair of substrates, the glass transition temperature (Tg) of a cured material, which is obtained by heat curing at 80° C. for 60 minutes of the composition of the claimed invention, is preferably 10 to 40° C. When two resin sheets are used as the pair of substrates, the display apparatus is sometimes required to have flexibility. In this case, the sealing agent preferably has flexibility and thus the glass transition temperature of the cured material from the composition preferably falls within the above-described range. Furthermore, when two glass substrates are used as the pair of substrates, interfacial peeling between the glass substrates and the sealing agent may occur due to the difference in linear expansion coefficients between the glass substrates and the sealing agent. In this case, when the glass transition temperature of the cured material is set within the above range, interfacial peeling rarely occurs.

The resin sheet used herein is preferably formed of a highly transparent resin. Specific examples thereof include polyethylene terephthalate, polymethyl methacrylate, polycarbonate, cyclic polyolefin (COC), polypropylene, polystyrene, poly(vinyl chloride), transparent ABS resin, transparent nylon, transparent polyimide, and polyvinyl alcohol.

Furthermore, the glass transition temperature of a cured material is obtained by measuring the glass transition temperature of a film having a thickness of 100 μm by DMS at a rate of temperature increase of 5° C./min, which film is obtained by heat curing at 80° C. for 60 minutes of the composition of the present invention.

A process for preparing the composition of the claimed invention is not particularly limited. The composition of the claimed invention can be prepared for instance by mixing components as mentioned above. Examples of means of mixing the components include, but are not particularly limited to, a twin arm stirrer, a roll kneader, a twin screw extruder, a ball-mill kneader, and a planetary stirrer. The composition of the claimed invention can be obtained by mixing the components mentioned above, filtrating the mixture through a filter to remove impurities and further applying a vacuum defoaming treatment to the resultant mixture. The obtained composition of the claimed invention is sealed in a glass bottle and a plastic container and stored. Since the composition is preferred to have a low moisture content as described above, the composition is preferably stored in a container having low moisture permeability.

The composition of the claimed invention is preferably used as a display edge-face sealing agent for sealing the edge-faces of various types of display apparatus.

Since the composition of the claimed invention has an appropriate low viscosity, the coating properties are good and the moisture resistance of the cured material is high. Accordingly, the composition of the claimed invention is used as a sealing agent for display apparatus having a liquid crystal element, an EL element, an LED element, or an electrophoretic display element; and preferably as a sealing agent for sealing the edge-face of the display apparatus having an electrophoretic display element. Examples of the electrophoretic display apparatus include an electronic paper display.

2. Display device and process for manufacturing display apparatus

The display apparatus of the claimed invention includes a display element such as an electrophoretic element and a pair of substrates sandwiching the display element, and has a structure where the gap between the substrates and formed in the peripheral edge portion of the pair of substrates is sealed with a sealing member. As the sealing member, a cured material from the display edge-face sealing agent according to the claimed invention can be used.

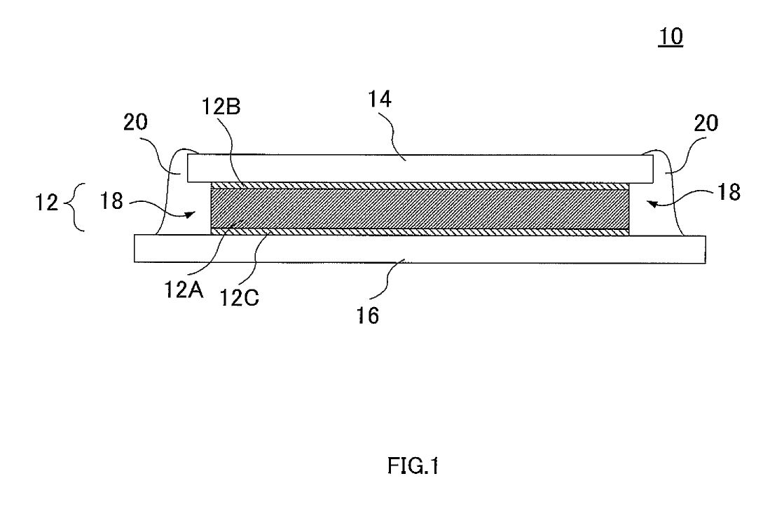

FIG. 1 shows a schematic view of an embodiment of the display apparatus of the claimed invention. Display device 10 has electrophoretic-system display element 12 and substrates 14 and 16 sandwiching display element 12, and has a structure in which gap 18 formed between the edge-faces of substrates 14 and 16 is sealed with sealing member 20.

Display element 12 has electrophoretic-system display layer 12A and transparent electrodes 12B and 12C for driving display layer 12A.

Substrates 14 and 16 may be glass plates or resin sheets. At least one of substrates 14 and 16, which serves as a display surface, is preferably a transparent glass plate or resin sheet. Examples of the transparent resin sheet include sheets formed of a polyester resin such as polyethylene terephthalate; an acrylic resin; or a polycarbonate resin. The thickness of each of substrates 14 and 16, which varies depending upon the use, can be set at about 0.1 to about 3 mm, and preferably 0.5 to 1.5 mm.

The size of gap 18 present between substrates 14 and 16 varies depending upon the use. The size of the gap in an electronic paper display is, for example, 20 to 500 μm, and more preferably 25 μm or less.

The display apparatus of the claimed invention can be manufactured as follows. The display apparatus is manufactured through a step 1) of obtaining a laminate having a display element and a pair of substrates sandwiching the display element; 2) applying or adding dropwise a display edge-face sealing agent to the gap between the pair of substrates that is formed in the peripheral edge portion of the laminate; and 3) curing the display edge-face sealing agent.

Means of applying or adding dropwise the display edge-face sealing agent to the peripheral edge portion of the laminate is not particularly limited. For example, a dispenser or a screen printer may be used.

The display edge-face sealing agent may be cured by heat curing or photo curing. From the perspective of limiting deterioration of the display element, heat curing is preferred. The reason for this is that when the display edge-face sealing agent is photo-cured by ultraviolet irradiation, the display element may be deteriorated by the ultraviolet irradiation, and that the production efficiency decreases when the sealing agent at the display apparatus edge-face is solely irradiated without irradiation of the display element.

The heat curing temperature is preferably, for example, 60 to 80° C., and more preferably 60 to 70° C., from the perspective of reducing damage to the display element. The time for heat curing, which varies depending upon the heat curing temperature and the amount of sealing agent, may be, for example, 30 to 90 minutes.

Accordingly, in a process for manufacturing the display apparatus of the claimed invention, the gap between the pair of substrates that is formed in the peripheral edge portion of the laminate is sealed with a sealing agent after a laminate having a display element and a pair of substrates sandwiching the display element is assembled. Since the sealing agent of the claimed invention has the appropriately low viscosity described above despite a high filler content, it can accurately fill the gap formed in the peripheral edge portion of the pair of substrates, even if it is thin. In addition, since the cured material from the sealing agent of the present invention is highly moisture resistant, the obtained display apparatus can maintain high adhesion strength even under a high temperature/high humidity environment.

### EXAMPLES

Components used in Examples and Comparative Examples will be described below.

(1) Liquid Epoxy Resin (Component Having a Moisture Content of 0.2 wt % or Less was Used)

A: Bisphenol A epoxy resin (JER828 manufactured by Mitsubishi Chemical Corporation, epoxy equivalent: 184 to 194 g/eq)

B: Bisphenol F epoxy resin (EPICLON 830S manufactured by DIC Corporation, epoxy equivalent: 165 to 177 g/eq)

C: Bisphenol E epoxy resin (R710 manufactured by Printer Corporation, epoxy equivalent: 160 to 180 g/eq)

D: Polysulfide modified-epoxy resin (FLEP-60 manufactured by Toray Fine Chemicals Co., Ltd., epoxy equivalent 280 g/eq)

(2) Liquid Epoxy Resin Curing Agent (Component Having a Moisture Content of 100 Weight ppm or Less was Used)

A: Mixture of 4-methyl hexahydrophthalic anhydride and hexahydrophthalic anhydride (RIKACID MH-700 manufactured by New Japan Chemical Co., Ltd.)

B: Tetrahydrophthalic anhydride (RIKACID THPA manufactured by New Japan Chemical Co., Ltd.)

C: Pentaerythritol tetrakis(3-mercaptopropionate)

D: Trimethylolpropane tris(3-mercaptopropionate)

E: Tris-[(3-mercaptopropionyloxy)-ethyl]-isocyanurate

F: Tetraethylene glycol bis(3-mercaptopropionate)

G: Dipentaerythritol hexakis(3-mercaptopropionate)

(3) Secondary or Tertiary Amine (Component Having a Moisture Content of 0.1 wt % or Less was Used)

A: Imidazole modified microcapsule (Novacure HX-3722 manufactured by Asahi Kasei Corporation)

B: Modified polyamine (FUJICURE FXR-1081 manufactured by Fuji Kasei Kogyo Co., Ltd., melting point: 121° C.)

C: Modified polyamine (EH-4342 manufactured by ADEKA Corporation, melting point: 80° C.)

(4) Filler (Component Having a Moisture Content of 1 wt % or Less was Used)

Inorganic filler: Silicon dioxide (S-100 manufactured by Nippon Shokubai Co., Ltd., spherical particles having an average primary particle size of 1.0 μm)

Organic filler: Acrylic fine particle (F351G manufactured by Ganz Chemical Co., Ltd., spherical particles having an average primary particle size of 0.3 μm)

(5) Silane Coupling Agent (Component Having a Moisture Content of 0.1 wt % or Less was Used)

Glycidoxypropyltrimethoxysilane (KBM403 manufactured by Shin-Etsu Chemical Co., Ltd.)

(6) Others (Component Having a Moisture Content of 0.1 wt % or Less was Used)

Solid epoxy resin: bisphenol A epoxy resin (JER1001 manufactured by Mitsubishi Chemical Corporation, epoxy equivalent: 450 to 500 g/eq, softening point: 64° C.)

### Example 1

A bisphenol A epoxy resin (JER828 manufactured by

Mitsubishi Chemical Corporation)(21 parts by weight) serving as the liquid epoxy resin (1); a mixture of 4-methyl hexahydrophthalic anhydride and hexahydrophthalic anhydride (RIKACID MH-700 manufactured by New Japan Chemical Co., Ltd.)(19 parts by weight) serving as the liquid epoxy resin curing agent (2); imidazole modified microcapsules (Novacure HX-3722 manufactured by Asahi Kasei Corporation)(12 parts by weight) serving as the amine; silicon dioxide (3) (S-100 manufactured by Nippon Shokubai Co., Ltd)(45 parts by weight) serving as the inorganic filler (4); acrylic fine particles (F351G manufactured by Ganz Chemical Co., Ltd.)(2 parts by weight) serving as the organic filler; and KBM403 (manufactured by Shin-Etsu Chemical Co., Ltd.) (1 weight part) serving as the silane coupling agent (5) were kneaded by three rolls. Thereafter, the kneaded product was filtrated through a filter and subjected to a vacuum defoaming treatment to obtain a composition (hereinafter referred to as a “sealing agent”). The sealing agent was prepared under low humidity conditions so as not to increase the moisture content in raw materials such as a liquid epoxy resin.

### Examples 2 and 3

Sealing agents were obtained in the same manner as in Example 1 except that the types of the liquid epoxy resin (1) were changed to those shown in Table 1.

### Example 4

A sealing agent was obtained in the same manner as in Example 1 except that the type and the blending ratio of the liquid epoxy resin (1) were changed to those shown in Table 1.

### Examples 5 to 10

Sealing agents were obtained in the same manner as in Example 1 except that the types of liquid epoxy resin (1) and that the types of liquid epoxy resin curing agent (2) were changed to those shown in Tables 1 and 2.

### Example 11

A sealing agent was obtained in the same manner as in Example 1 except that the amount of the inorganic filler (4) was changed to 47 parts by weight and that no organic filler was included in the sealing agent.

### Examples 12 and 13

Sealing agents were obtained in the same manner as in Example 2 except that the types and amounts of the liquid epoxy resin curing agent (2) and the secondary or tertiary amine (3) were changed to those shown in Table 2.

### Example 14

A sealing agent was obtained in the same manner as in Example 2 except that the amount of the liquid epoxy resin (1) was changed to 19 parts by weight and that the solid epoxy resin (6) (2 parts by weight) was included in the sealing agent.

### Example 15

A sealing agent was obtained in the same manner as in Example 6 except that the amount of the inorganic filler (4) was changed to 47 parts by weight and that an organic filler was not included in the sealing agent.

### Example 16

A sealing agent was prepared in the same manner as in Example 6 and water was added such that the sealing agent had a moisture content of 0.6 wt %.

### Comparative Example 1

A sealing agent was obtained in the same manner as in Example 1 except that a solid epoxy resin (13 parts by weight) was included instead of the liquid epoxy resin (1) and that the amounts of the liquid epoxy resin curing agent (2) and inorganic filler (4) were changed to those shown in Table 3.

### Comparative Examples 2 and 3

Sealing agents were obtained in the same manner as in Example 1 except that the liquid epoxy resin curing agent (2) was not included in the sealing agent and that the formulations were changed to those shown in Table 3.

### Comparative Examples 4 and 5

Sealing agents were obtained in the same manner as in Example 1 except that the organic filler (4) was not included in the sealing agent and that the formulations were changed to those shown in Table 3.

### Comparative Example 6

A sealing agent was obtained in the same manner as in Example 1 except that the secondary or tertiary amine (3) was not included in the sealing agent and that the formulation was changed to that shown in Table 3.

### Comparative Example 7

A sealing agent was obtained in the same manner as in Example 11 except that the amounts of the liquid epoxy resin (1), liquid epoxy resin curing agent (2) and inorganic filler (4) and organic filler were changed to those shown in Table 3.

The sealing agents obtained in Examples and Comparative Examples were evaluated for moisture content, viscosity, adhesion strength, cell distortion, reliability under high temperature and high humidity conditions, and glass transition temperature (Tg) as follows.

1) Moisture Content (wt %)

The moisture contents of the sealing agents obtained were measured by the Karl Fischer's method.

2) Viscosity

The viscosity of the sealing agents obtained was measured by an E-type viscometer at 25° C. and 2.5 rpm.

3) Adhesion Strength

To the sealing agents obtained, spherical silica particles having an average particle size of 20 μm were added to a volume of 1% as a spacer, and mixed. The mixture was defoamed. On a non-alkali glass of 25 mm×45 mm in size with a thickness of 0.7 mm, a circular seal pattern of 1 mm in diameter was drawn using the spacer-containing sealing agent via a screen plate.

On the non-alkali glass having a seal pattern drawn thereon, a counter alkali glass was overlaid and secured thereto. The two glass plates were bonded together by heating at 80° C. for minutes. The two glass plates bonded in this manner (hereinafter referred to as a “test specimen”) were stored in a constant-temperature vessel of 25° C. having a humidity of 50% for 24 hours. Thereafter, the test specimen was removed from the constant-temperature vessel and measured for plane tensile strength by a tensile tester (INTESCO Co., Ltd.) at a tensile rate of 2 mm/min.

4) Cell Distortion Test

On a non-alkali glass measuring 50 mm×50 mm and 0.7 mm in thickness, spherical spacers having an average particle size of 20 μm were scattered (disposed). On the substrate, a counter glass substrate measuring 40 mm×40 mm was overlaid. The obtained sealing agent was applied by a dispenser to the gap (5 μm) present between the substrates and formed in the peripheral edge portions thereof. Thereafter, the sealing agent was cured by heating at 80° C. for 60 minutes to prepare a cell.

The presence or absence of distortion of the cell was evaluated based on the observation of the presence or absence of a Newton ring in the center of the cell.

No Newton ring is observed in the center of the cell: no distortion is present (Good)

Newton ring is observed in the center of the cell: distortion is present (Bad)

5) Test for Reliability Under High Temperature/High Humidity Conditions

On a non-alkali glass of 50 mm×50 mm in size with a thickness of 0.7 mm, a dried calcium carbonate fine powder (10 mg) was placed. On the substrate, a counterpart glass substrate of 40 mm×40 mm in size was overlaid. The sealing agent was applied by a dispenser to the gap (100 μm) present between the substrates and formed in the peripheral edge portions thereof. Thereafter, the sealing agent was cured by heating at 80° C. for 60 minutes to prepare a cell.

The obtained cell was allowed to stand at (1) 60° C., 95% RH for 1,000 hours, and (2) 85° C., 85% RH for 1,000 hours. The weight of the cell was measured before and after the standing. The smaller the cell weight change before and after standing, the higher the moisture resistance.

Cell weight after standing is 100% or more to 102% or less the cell weight before standing: Good

Cell weight after standing is over 102% to 105% or less the cell weight before standing: Fair

Cell weight after standing is over 105% the cell weight before standing: Bad

6) Glass Transition Temperature (Tg)

The sealing agent containing a spacer and prepared in Section 1) above was applied to a release paper sheet by use of an applicator so that the thickness of film was 100 μm. The release paper sheet having a coating film of the sealing agent formed thereon was kept in a hot-air drying oven of 80° C. for 60 minutes, then taken out and cooled. Thereafter, the coating film was removed from the release paper sheet to obtain a film having a thickness of 100 μm. The glass transition temperature (Tg) of the obtained film was measured by DMS-6100 manufactured by Seiko Instruments Inc. at a temperature increase rate of 5° C./min.

The evaluation results of Examples 1 to 8, the evaluation results of Examples 9 to 16 and evaluation results of Comparative Examples 1 to 7 are shown in Table 1, Table 2 and Table 3, respectively. The units of numerical values of formulations of Tables 1 to 3 are all “parts by weight”.

TABLE 1

| | | | Example 1 | Example 2 | Example 3 | Example 4 | Example 5 | Example 6 | Example 7 | Example 8 |
|---|---|---|---|---|---|---|---|---|---|---|
| Formulation | Liquid epoxy resin (1) | A | 21 | | | | | | | |
| | | B | | 21 | | | 21 | 21 | 21 | 21 |
| | | C | | | 21 | | | | | |
| | | D | | | | 10 | | | | |
| | Solid epoxy resin (6) | | | | | | | | | |
| | Liquid epoxy resin curing agent (2) | A | 19 | 19 | 19 | 25 | | | | |
| | | B | | | | | 19 | | | |
| | | C | | | | | | 19 | | |
| | | D | | | | | | | 19 | |
| | | E | | | | | | | | 19 |
| | | F | | | | | | | | |
| | | G | | | | | | | | |
| | Secondary/tertiary amine (3) | A | 12 | 12 | 12 | 12 | 12 | 12 | 12 | 12 |
| | | B | | | | | | | | |
| | | C | | | | | | | | |

| | Inorganic filler (4) | | 45 | 45 | 45 | 50 | 45 | 45 | 45 | 45 |
|---|---|---|---|---|---|---|---|---|---|---|
| | Organic filler | | 2 | 2 | 2 | 2 | 2 | 2 | 2 | 2 |
| | Filler content ratio* | | 90.4 | 90.4 | 90.4 | 110.6 | 90.4 | 90.4 | 90.4 | 90.4 |
| | Silane coupling agent (5) | | 1 | 1 | 1 | 1 | 1 | 1 | 1 | 1 |
| Evaluation | (1) Moisture content (wt %) | | 0.1 | 0.1 | 0.1 | 0.1 | 0.1 | 0.1 | 0.1 | 0.1 |
| | (2) Viscosity (Pa · s) | | 5 | 4 | 3 | 15 | 4 | 4 | 4 | 4 |
| | (3) Adhesion strength (MPa) | | 9 | 10 | 10 | 8 | 10 | 7 | 7 | 7 |
| | (4) Cell distortion test | | Fair | Good | Good | Good | Good | Good | Good | Good |
| | (5) Reliability under | 60° C. 95% RH | Good | Good | Good | Good | Good | Good | Good | Good |
| | high temperature/ | 85° C. 85% RH | Good | Good | Good | Fair | Good | Good | Good | Good |
| | high humidity | | | | | | | | | |
| | conditions | | | | | | | | | |

| | | | | | | | | |
|---|---|---|---|---|---|---|---|---|
| (6) Glass transition temperature | 105 | 100 | 95 | 35 | 95 | 70 | 65 | 50 |
| Tg (° C.) | | | | | | | | |

*indicates a ratio (parts by weight) of the total amount of fillers with respect to 100 parts by weight of the total amount of components (1), (2) and (3).

TABLE 2

| | | | | Example | Example | Example | Example | Example | Example | Example |
|---|---|---|---|---|---|---|---|---|---|---|
| | | | Example 9 | 10 | 11 | 12 | 13 | 14 | 15 | 16 |
| Formulation | Liquid epoxy resin (1) | A | | | | | | | | |
| | | B | 21 | 21 | 21 | 21 | 21 | 19 | 21 | 21 |
| | | C | | | | | | | | |
| | | D | | | | | | | | |
| | Solid epoxy resin (6) | | | | | | | 2 | | |
| | Liquid epoxy resin curing agent (2) | A | | | 19 | 10 | 10 | 19 | | |
| | | B | | | | | | | | |
| | | C | | | | | | | 19 | 19 |
| | | D | | | | | | | | |
| | | E | | | | | | | | |
| | | F | 19 | | | | | | | |
| | | G | | 19 | | | | | | |
| | Secondary/tertiary amine (3) | A | 12 | 12 | 12 | | | 12 | 12 | 12 |
| | | B | | | | 21 | | | | |
| | | C | | | | | 21 | | | |

| | Inorganic filler (4) | | 45 | 45 | 47 | 45 | 45 | 45 | 47 | 45 |
|---|---|---|---|---|---|---|---|---|---|---|
| | Organic filler | | 2 | 2 | 0 | 2 | 2 | 2 | 0 | 2 |
| | Filler content ratio* | | 90.4 | 90.4 | 90.4 | 90.4 | 90.4 | 90.4 | 90.4 | 90.4 |
| | Silane coupling agent (5) | | 1 | 1 | 1 | 1 | 1 | 1 | 1 | 1 |
| Evaluation | (1) Moisture content (wt %) | | 0.1 | 0.1 | 0.1 | 0.1 | 0.1 | 0.1 | 0.1 | 0.6 |
| | (2) Viscosity (Pa · s) | | 4 | 4 | 4 | 12 | 14 | 6 | 4 | 4 |
| | (3) Adhesion strength (MPa) | | 7 | 7 | 9 | 10 | 11 | 12 | 6 | 7 |
| | (4) Cell distortion test | | Good | Good | Good | Good | Good | Good | Good | Good |
| | (5) Reliability under | 60° C. 95% RH | Good | Good | Good | Good | Good | Good | Good | Bad |
| | high temperature/ | 85° C. 85% RH | Good | Good | Good | Good | Good | Good | Good | Bad |
| | high humidity | | | | | | | | | |
| | conditions | | | | | | | | | |

| | | | | | | | | |
|---|---|---|---|---|---|---|---|---|
| (6) Glass transition temperature | 45 | 50 | 90 | 97 | 85 | 90 | 72 | 70 |
| Tg (° C.) | | | | | | | | |

*indicates ratio (parts by weight) of the total amount of fillers to 100 parts by weight of the total amount of components (1), (2) and (3).

TABLE 3

| | | | Comparative | Comparative | Comparative | Comparative | Comparative | Comparative | Comparative |
|---|---|---|---|---|---|---|---|---|---|
| | | | Example 1 | Example 2 | Example 3 | Example 4 | Example 5 | Example 6 | Example 7 |
| Formulation | Liquid epoxy resin (1) | A | | | | | | | |
| | | B | | 30 | 40 | 40 | 21 | | 24 |
| | | C | | | | | | 30 | |
| | | D | | | | | | | |
| | Solid epoxy resin (6) | | 13 | | | | | | |
| | Liquid epoxy resin curing | A | 20 | | | 21 | 10 | 22 | 6 |
| | agent (2) | B | | | | | | | |
| | | C | | | | | | | |
| | | D | | | | | | | |
| | | E | | | | | | | |
| | | F | | | | | | | |
| | | G | | | | | | | |
| | Secondary/tertiary amine (3) | A | 12 | 12 | 17 | 13 | 8 | | 12 |
| | | B | | | | | | | |
| | | C | | | | | | | |

| | Inorganic filler (4) | | 55 | 55 | 40 | 25 | 60 | 45 | 55 |
|---|---|---|---|---|---|---|---|---|---|
| | Organic filler | | 2 | 2 | 2 | 0 | 0 | 2 | 2 |
| | Filler content ratio* | | 135.7 | 135.7 | 73.7 | 33.8 | 153.8 | 90.4 | 135.7 |
| | Silane coupling agent (5) | | 1 | 1 | 1 | 1 | 1 | 1 | 1 |
| Evaluation | (1) Moisture content (wt %) | | 0.1 | 0.1 | 0.1 | 0.1 | 0.1 | 0.1 | 0.1 |
| | (2) Viscosity (Pa · s) | | 53 | 78 | 30 | 3 | 48 | 4 | 58 |
| | (3) Adhesion strength (MPa) | | 10 | 5 | 6 | 8 | 7 | 10 | 6 |
| | (4) Cell distortion test | | Good | Bad | Bad | Good | Fair | Good | Bad |
| | (5) Reliability under | 60° C. | Fair | Fair | Good | Fair | Good | Good | Fair |
| | high temperature/high | 95% RH | Bad | Bad | Good | Bad | Fair | Bad | Bad |
| | humidity conditions | 85° C. | | | | | | | |
| | | 85% RH | | | | | | | |

| | | | | | | | |
|---|---|---|---|---|---|---|---|
| (6) Glass transition temperature | 85 | 107 | 115 | 97 | 93 | 45 | 105 |
| Tg (° C.) | | | | | | | |

*indicates ratio (parts by weight) of the total amount of fillers to 100 parts by weight of the total amount of components (1), (2) and (3).

As shown in Tables 1 and 2, the sealing agents in Examples 1 to 16 were found to have a viscosity as low as 15 Pa·s or less despite having a high filler content. Accordingly, the sealing agents of Examples 1 to 15 are able to sufficiently fill the gap between substrates, and the reliability of the obtained cell under high temperature/high humidity conditions was found to be high.

However, Example 16 is low in reliability under high temperature/high humidity conditions compared to Examples 1 to 15 since the moisture content in the sealing agent is high.

In contrast, as shown in Table 3, the sealing agents of Comparative Examples 1 to 3, 5, and 7 all have high viscosity despite having a relatively low filler content. Accordingly, the sealing agents of Comparative Examples 1 to 3, 5, and 7 were unable to sufficiently fill the gap between substrates, and the reliability of the obtained cell under high temperature/high humidity conditions was found to be low.

Particularly, it can be seen that the sealing agent of Comparative Example 1 which contains no liquid epoxy resin but contains a solid epoxy resin, and the sealing agents of Comparative Examples 2 and 3 which contain no liquid epoxy resin curing agent exhibited high viscosity, low reliability under high temperature/high humidity conditions, and large cell distortion. Furthermore, in the sealing agent of Comparative Example 4, the reliability under high temperature/high humidity conditions is considered to be low because the filler content is low. On the other hand, in the sealing agent of Comparative Example 5, because the filler content is extremely high, a gap cannot be sealed with a uniform thickness, thereby causing cell distortion to occur and sealing properties to deteriorate. With the sealing agent of Comparative Example 6, since the secondary or tertiary amine (3) is not included, the heat resistance (Tg) of the cured material is low and reliability under high temperature conditions is also low.

In particular the possible cause of cell distortion observed in Comparative Examples 2 and 3 where no liquid epoxy resin curing agent is added is as follows. Because the cross-linked product obtained through the reaction between an epoxy resin and a liquid epoxy resin curing agent is considered flexible, the cell was not distorted. However, the cross-linked product (polyether) obtained in each of Comparative Examples 2 and 3 through a ring opening reaction of a liquid epoxy resin with a secondary or tertiary amine is fragile, and thus the cell was distorted.

In the sealing agent of Comparative Example 7, the amount of liquid epoxy resin curing agent (2) is small compared to the amount of secondary or tertiary amine (3). Accordingly, viscosity increases and the sealing agent cannot sufficiently fill the gap between substrates. As a result, the reliability under high temperature/high humidity conditions is thought to be reduced. In addition, since the amount of epoxy resin curing agent is low, the flexibility of a cross-linked product is not sufficient, and the cell was distorted in a manner similar to that of Comparative Examples 2 and 3.

### INDUSTRIAL APPLICABILITY

According to the present invention, is possible to provide a display edge-face sealing agent having viscosity stability and a viscosity low enough for it to fill even a thin gap, and to provide a cured material having high moisture resistance.

### REFERENCE SIGNS LIST

10 Display apparatus
12 Display device
12A Display layer
12B, 12C Transparent electrodes
14, 16 Substrates
18 Gap
20 Sealing member

1. A resin composition comprising:
(1) an epoxy resin that is liquid at 23° C.;
(2) an epoxy resin curing agent that is liquid at 23° C., the epoxy resin curing agent being selected from the group consisting of an acid anhydride and a thiol compound having two or more mercapto groups in a molecule thereof;
(3) a secondary or tertiary amine that is solid at 23° C., or microcapsules encapsulating therein the secondary or tertiary amine; and
(4) a filler, wherein
an amount of the component (4) in the composition is 50 to 150 parts by weight based on 100 parts by weight of the total amount of the components (1), (2) and (3), and
the composition has a viscosity at 25° C. and 2.5 rpm of 0.5 to 50 Pa·s as measured by an E-type viscometer.

2. A composition for a display edge-face sealing agent comprising the composition according to claim 1.

3. The composition according to claim 2, wherein the composition has a moisture content of 0.5 wt % or less.

4. The composition according to claim 2, wherein the filler comprises an inorganic filler and an organic filler.

5. The composition according to claim 2, wherein the filler is a spherical filler having an average particle size of 0.1 to 20 μm.

6. The composition according to claim 2, wherein the epoxy resin that is liquid at 23° C. is at least one resin selected from the group consisting of a bisphenol A epoxy resin, a bisphenol F epoxy resin, a bisphenol E epoxy resin, and a polysulfide modified epoxy resin.

7. The composition according to claim 2, wherein a content ratio of the component (3) to the component (2) is 0.2 to 1.2 by weight.

8. The composition according to claim 2, wherein
the secondary or tertiary amine that is solid at 23° C. is in the form of fine particles having a melting point of 60 to 180° C. selected from the group consisting of an imidazole compound, and a modified polyamine; and
the fine particles have an average particle size of 0.1 to 10 μm.

9. The composition according to claim 2, wherein
the microcapsules each includes:
a core formed of at least one secondary or tertiary amine selected from the group consisting of an imidazole compound and a modified polyamine; and
a capsule wall having a melting point of 60 to 180° C., the capsule wall encapsulating the secondary or tertiary amine, and wherein
the microcapsules have an average particle size of 0.1 to 10 μm.

10. The composition according to claim 4, wherein
the organic filler is at least one fine particle having a melting point or softening point of 60 to 120° C. selected from the group consisting of a silicon fine particle, an acrylic fine particle, a styrene fine particle, and a polyolefin fine particle, or at least one wax selected from the group consisting of carnauba wax, a microcrystalline wax, a modified microcrystalline wax, Fischer-Tropsch wax, and a modified Fischer-Tropsch wax.

11. The composition according to claim 2, wherein a film having a thickness of 100 μm obtained by heat curing of the composition at 80° C. for 60 minutes has a glass transition temperature Tg of 30 to 110° C. as measured by DMS at a rate of temperature increase of 5° C./min.

12. The composition according to claim 2, wherein a film having a thickness of 100 μm obtained by heat curing of the composition at 80° C. for 60 minutes has a glass transition temperature Tg of 10 to 40° C. as measured by DMS at a rate of temperature increase of 5° C./min.

13. The composition according to claim 2, wherein the display apparatus displays information by an electrophoretic system.

14. The composition according to claim 2, wherein the display apparatus is an electronic paper display.

15. A display apparatus comprising:
a display element;
a pair of substrates sandwiching the display element; and
a cured material from the composition according to claim 2 sealing a gap between the pair of substrates, the gap being formed in a peripheral edge portion of the pair of substrates.

16. The display apparatus according to claim 15, wherein
one of the pair of substrates is a glass substrate and the other is a resin sheet; and
the cured material has a glass transition temperature Tg of 30 to 110° C. as measured by DMS at a thickness of 100 μm and at a rate of temperature increase of 5° C./min.

17. The display apparatus according to claim 15, wherein
the pair of substrates are both glass substrates or resin sheets, and
the cured material has a glass transition temperature Tg of 10 to 40° C. as measured by DMS at a rate of temperature increase of 5° C./min, where the cured material has a thickness of 100 μm.

18. The display apparatus according to claim 15, wherein the gap between the pair of substrates has a size of 20 to 500 μm.

19. A process for manufacturing a display apparatus, comprising:
providing a laminate having a display element and a pair of substrates sandwiching the display element;
applying or adding dropwise the composition according to claim 1 to a gap between the pair of substrates, the gap being formed in a periphery edge portion of the laminate; and
curing the display edge-face sealing agent applied or added dropwise.
